(19) United States
(12) Patent Application Publication
(10) Pub. No.: US 2009/0142892 A1
(43) Pub. Date: Jun. 4, 2009

(54) Method of fabricating semiconductor device having thin strained relaxation buffer pattern and related device

(76) Inventors: Byeong-Chan Lee, Yongin-si (KR); Si-Young Choi, Seongnam-si (KR); Yong-Hoon Son, Yongin-si (KR); In-Soo Jung, Bucheon-si (KR); Min-Gu Kang, Yongin-si (KR); Pil-Kyu Kang, Anyang-si (KR)

Correspondence Address: LEE & MORSE, P.C., 3141 FAIRVIEW PARK DRIVE, SUITE 500, FALLS CHURCH, VA, 22042, US

(21) Appl. No.: 11/984,538

(22) Filed: Nov. 19, 2007

(30) Foreign Application Priority Data
Nov. 20, 2006 (KR) 10-2006-0114577

(51) Int. Cl. H01L 21/336; H01L 21/20

(52) U.S. Cl. 438/218; 438/487; 257/E21.09; 257/E21.409

(57) ABSTRACT

A method of fabricating a semiconductor device includes forming a buffer pattern on a substrate, the buffer pattern including germanium, recrystallizing the buffer pattern to form a strained relaxation buffer pattern, and forming a tensile silicon cap on the strained relaxation buffer pattern, the cap being under tensile strain.

### BACKGROUND OF THE INVENTION

1. Field of the Invention

Embodiments relate to a semiconductor device, and more particularly, to a semiconductor device having a thin strained relaxation buffer pattern, and a method of fabricating the same.

2. Description of the Related Art

Extensive research is being carried out to meet the demand for high-speed and highly integrated semiconductor devices. A typical semiconductor device includes a discrete device such as a metal-oxide semiconductor (MOS) transistor. As development advances, the gate of the MOS transistor is scaled down, and the channel region below the gate is also getting narrower. Mobility of carriers that move through the channel region has a direct effect on drain current. Accordingly, research into ways of applying a physical stress to the channel region to improve the mobility of carriers is underway.

### SUMMARY OF THE INVENTION

Embodiments are therefore directed to a semiconductor device having a thin strained relaxation buffer pattern, and a method of fabricating the same, which substantially overcome one or more of the problems due to the limitations and disadvantages of the related art.

It is therefore a feature of an embodiment to provide a method of forming a strained relaxation buffer pattern having a small thickness, and a semiconductor device formed thereby.

It is therefore another feature of an embodiment to provide a method of forming a strained relaxation buffer pattern suitable for forming a CMOS device, wherein an NMOS transistor has a cap under the gate electrode that is under biaxial tensile strain, and a PMOS transistor has a cap under the gate electrode.

At least one of the above and other features and advantages may be realized by providing a method of fabricating a semiconductor device, including forming a buffer pattern on a substrate, the buffer pattern including germanium, recrystallizing the buffer pattern to form a strained relaxation buffer pattern, and forming a tensile silicon cap on the strained relaxation buffer pattern, the cap being under tensile strain.

A concentration of germanium in the strained relaxation buffer pattern may increase in a direction from the substrate toward the cap. The buffer pattern may be a silicon-germanium buffer pattern. The buffer pattern may be a germanium buffer pattern. Recrystallizing the buffer pattern may include a LEG process. The LEG process may include irradiating a laser onto the buffer pattern so as to melt the buffer pattern and a surface of the substrate underneath the buffer pattern.

The method may further include, prior to recrystallizing the buffer pattern, forming an isolation layer defining an active region in the substrate, and recessing a top surface of the active region. The isolation layer may be formed prior to forming the buffer pattern.

The buffer pattern may be formed to a thickness of about 1 nm to about 300 nm. The buffer pattern may be formed to a thickness of about 10 nm to about 20 nm.

The method may further include forming a gate electrode over the cap, such that the cap is interposed between the gate electrode and the strained relaxation buffer pattern, and the strained relaxation buffer pattern crosses beneath the gate electrode. The gate electrode may be a gate electrode of an NMOS transistor, and the method may further include forming a PMOS transistor adjacent to the NMOS transistor.

Forming the PMOS transistor may include forming a second buffer pattern on the substrate, the second buffer pattern including germanium, forming a second cap on the second buffer pattern, and forming a second gate electrode on the second cap.

The buffer pattern and the second buffer pattern may be formed at the same time. The buffer pattern and the second buffer pattern may have a same thickness, and the cap and the second cap may have a same thickness.

The second buffer pattern may not be recrystallized. The method may further include, prior to recrystallizing the buffer pattern, forming a mask pattern that exposes the buffer pattern and covers the second buffer pattern, and recrystallizing the buffer pattern using a LEG process.

Forming the PMOS transistor may further include introducing a P-type impurity into the second buffer pattern on opposite sides of the second gate electrode.

The second buffer pattern may be recrystallized to form a second strained relaxation buffer pattern prior to forming the second cap.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1 to 6 illustrate cross-sectional views of stages in a method of fabricating a semiconductor device having a thin strained relaxation buffer pattern according to a first embodiment; and

FIGS. 7 to 12 illustrate cross-sectional views of stages in a method of fabricating a semiconductor device having a thin strained relaxation buffer pattern according to a second embodiment.

### DETAILED DESCRIPTION OF THE INVENTION

Korean Patent Application No. 10-2006-0114577, filed Nov. 20, 2006, in the Korean Intellectual Property Office, and entitled: “Method of Fabricating Semiconductor Device Having Thin Strained Relaxation Buffer Pattern and Related Device,” is incorporated by reference herein in its entirety.

Embodiments will now be described more fully hereinafter with reference to the accompanying drawings; however, they should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

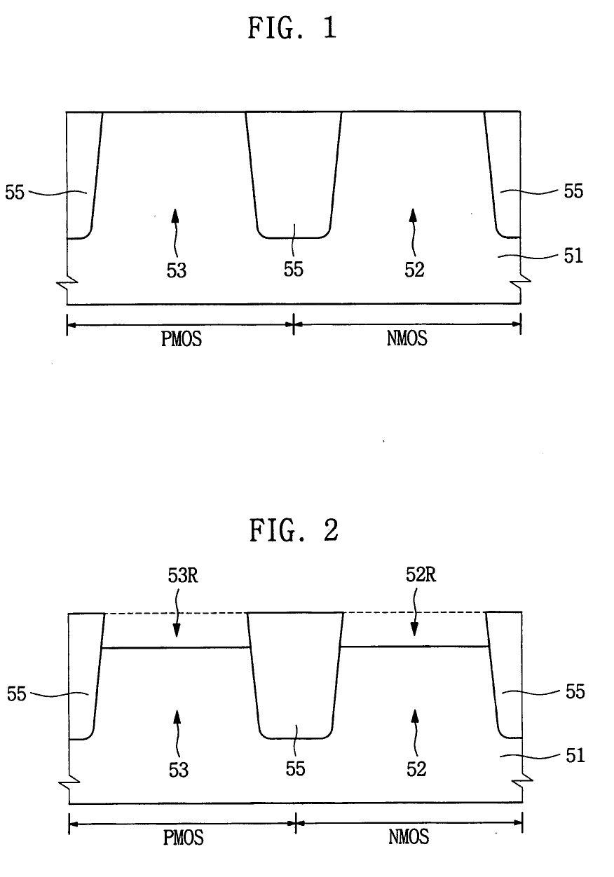

FIGS. 1 to 6 illustrate cross-sectional views of stages in a method of fabricating a semiconductor device having a thin strained relaxation buffer pattern according to a first embodiment. Referring to FIG. 1, an isolation layer 55 defining first and second active regions 52 and 53 may be formed in a semiconductor substrate 51. Top surfaces of the active regions 52 and 53, and a top surface of the isolation layer 55 may be exposed on substantially the same plane.

The semiconductor substrate 51 may be, e.g., a silicon (Si) substrate such as a silicon wafer. The semiconductor substrate 51 may include an n-channel metal-oxide semiconductor (NMOS) region and a p-channel metal-oxide semiconductor (PMOS) region. A shallow trench isolation (STI) technique may be applied to form the isolation layer 55. The isolation layer 55 may be formed of an insulating layer such as a silicon oxide layer.

The first active region 52 may be in the NMOS region, and the second active region 53 may be in the PMOS region. P-type impurity ions may be implanted into the first active region 52 to form a p-well, and/or n-type impurity ions may be implanted into the second active region 53 to form an n-well (not shown).

Referring to FIG. 2, the exposed surfaces of the active regions 52 and 53 may be etched to form recessed regions 52R and 53R. A dry-etching process having an etch selectivity between the active regions 52 and 53 and the isolation layer 55 may be employed to form the recessed regions 52R and 53R. In another implementation, an in-situ etching process using HCl may be employed to form the recessed regions 52R and 53R. After forming the recessed regions 52R and 53R, the respective top surfaces of the active regions 52 and 53 may be lower than the top surface of the isolation layer 55.

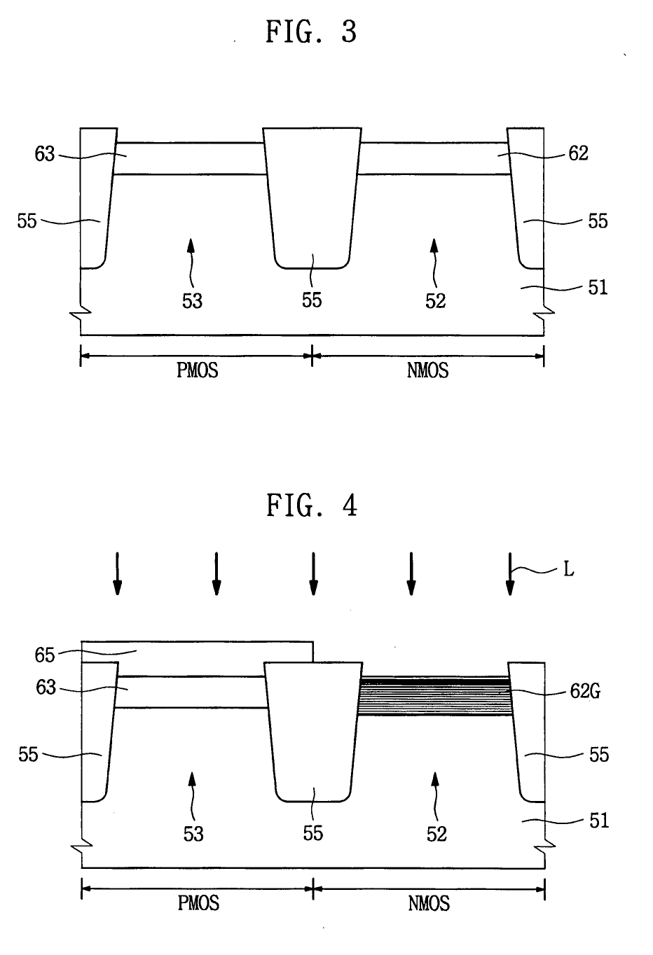

Referring to FIG. 3, a first buffer pattern 62 may be formed on the first active region 52. A second buffer pattern 63 may be formed on the second active region 53, e.g., at the same time the first buffer pattern 62 is formed. The buffer patterns 62 and 63 may be formed such that the top surfaces are lower than the top surface of the isolation layer 55.

The buffer patterns 62 and 63 may be formed of, e.g., a silicon germanium (SiGe) layer. The buffer patterns 62 and 63 may be formed to a thickness of about 1 nm to about 300 nm. In an implementation, the buffer patterns 162 and 163 may be formed to a thickness of about 10 nm to about 20 nm. A selective epitaxial growth (SEG) technique may be employed to form the buffer patterns 62 and 63, such that the buffer patterns 62 and 63 may grow upward from the surfaces of the active regions 52 and 53. Growth of the buffer patterns 62 and 63 may not occur on the isolation layer 55. The buffer patterns 62 and 63 may have a biaxially strained structure due to a difference in lattice constant between the germanium and the silicon.

Referring to FIG. 4, a mask pattern 65 may be formed on the semiconductor substrate 51 having the buffer patterns 62 and 63. The mask pattern 65 may be formed to cover one of the buffer patterns, e.g., the second buffer pattern 63. For example, the mask pattern 65 may be formed to cover the PMOS region and to expose the NMOS region. In this case, the second buffer pattern 63 on the second active region 53 may be covered with the mask pattern 65, and the first buffer pattern 62 on the first active region 52 may be exposed.

The first buffer pattern 62 may be recrystallized to form a strained relaxation buffer pattern 62G. In an implementation, a laser epitaxial growth (LEG) process may be performed to recrystallize the first buffer pattern 62, yielding a strained relaxation buffer pattern 62G. The LEG process may include irradiating a laser L onto the first buffer pattern 62. The laser L irradiated onto the first buffer pattern 62 may have an energy density high enough to melt the first buffer pattern 62. In an implementation, an entire thickness of the first buffer pattern 62 may be melted. In an implementation, the entire thickness of the first buffer pattern 62 may be melted, and a top surface of the first active region 52 that underlies the first buffer pattern 62 may also be melted.

While the laser L is irradiated onto the first buffer pattern 62, the mask pattern 65 may act to protect the second buffer pattern 63. The mask pattern 65 may be formed of a material layer capable of blocking the laser L. In an implementation, the mask pattern 65 may be formed of a silicon nitride layer and/or a silicon oxide layer.

The LEG process may melt and recrystallize the silicon and germanium in the first buffer pattern 62 to form the strained relaxation buffer pattern 62G. A graded germanium profile may be produced in the strained relaxation buffer pattern 62G by the melting and recrystallization. In particular, a germanium concentration profile in the strained relaxation buffer pattern 62G may show a decrease toward the first active region 52, and an increase toward a surface of the strained relaxation buffer pattern 62G, i.e., the germanium concentration of the strained relaxation buffer pattern 62G may be lower where it interfaces with the first active region 52 than it is at the top surface of the strained relaxation buffer pattern 62G. The top surface of the strained relaxation buffer pattern 62G may exhibit a relaxed structure due to a difference in lattice constant between the germanium and the silicon.

Subsequently, the mask pattern 65 may be removed to thereby expose the second buffer pattern 63.

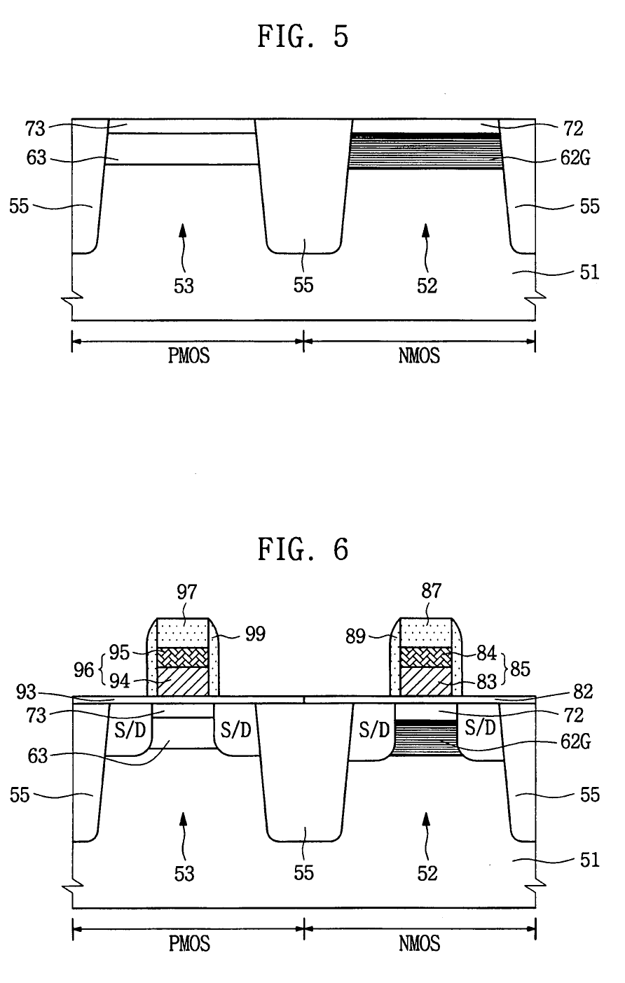

Referring to FIG. 5, a tensile silicon cap layer 72 may be formed on the strained relaxation buffer pattern 62G, and a silicon cap layer 73 may be formed on the second buffer pattern 63. The tensile silicon cap layer 72 and the silicon cap layer 73 may be formed using, e.g., a SEG technique. The tensile silicon cap layer 72 may exhibit a tensile strain in the silicon layer due to effects brought on by the strained relaxation buffer pattern 62G having a relaxed structure, i.e., the relaxed structure of the strained relaxation buffer pattern 62G may result in a tensile strain in the silicon layer formed thereon.

As described above, the surface of the strained relaxation buffer pattern 62G may have the relaxed structure as a result of the recrystallization using the LEG process. The strained relaxation buffer pattern 62G having the graded germanium profile may be sufficiently formed using a very thin first buffer pattern 62, e.g., having a thickness of only about 10 nm to about 20 nm. Such a small thickness is in distinction to conventional strained structures that require a thick graded silicon-germanium layer in order to avoid crystal defects (dislocations) in the silicon-germanium layer, which would cause crystal defects in the strained silicon layer formed thereon. Such a small thickness also avoids other drawbacks associated with the conventional thick graded silicon-germanium layers, such as the need to form the thick graded silicon-germanium layer before forming the STI region, which results in degradation of the strain characteristics of the silicon-germanium layer during annealing, and the deleterious effects of the thick graded silicon-germanium layer on heat transport out of the transistor.

Referring to FIG. 6, an NMOS gate dielectric layer 82 may be formed on the tensile silicon cap layer 72. The NMOS gate dielectric layer 82 may be formed of, e.g., a silicon oxide layer, a silicon oxynitride layer, a silicon nitride layer, a high-k dielectric layer, or a combination thereof.

An NMOS gate electrode 85 crossing the tensile silicon cap layer 72 may be formed on the NMOS gate dielectric layer 82. A first polysilicon pattern 83 and a first silicide pattern 84 may be sequentially stacked on the NMOS gate dielectric layer 82 to form the NMOS gate electrode 85. The first polysilicon pattern 83 may be formed of, e.g., an impurity-doped polysilicon layer. The first silicide pattern 84 may be formed of, e.g., a metal silicide layer such as a titanium silicide (TiSi) layer, a tantalum silicide (TaSi) layer, a tungsten silicide (WSi) layer, or a nickel silicide (NiSi) layer.

In an implementation, a first gate capping pattern 87 may be formed covering the NMOS gate electrode 85. The first gate capping pattern 87 may be formed of, e.g., an insulating layer such as a silicon nitride layer. First spacers 89 may be formed on sidewalls of the NMOS gate electrode 85. The first spacers 89 may be formed of, e.g., a silicon oxide layer, a silicon oxynitride layer, a silicon nitride layer, or a combination thereof.

A PMOS gate dielectric layer 93 may be formed on the silicon cap layer 73. The PMOS gate dielectric layer 93 may be formed of, e.g., a silicon oxide layer, a silicon oxynitride layer, a silicon nitride layer, a high-k dielectric layer, or a combination thereof.

A PMOS gate electrode 96 crossing the silicon cap layer 73 may be formed on the PMOS gate dielectric layer 93. A second polysilicon pattern 94 and a second silicide pattern 95 may be sequentially stacked on the PMOS gate dielectric layer 93 to form the PMOS gate electrode 96. The second polysilicon pattern 94 may be formed of, e.g., an impurity-doped polysilicon layer. The second silicide pattern 95 may be formed of, e.g., a metal silicide layer such as a TiSi layer, a TaSi layer, a WSi layer, or a NiSi layer.

In an implementation, the PMOS gate electrode 96 may be formed to include the impurity-doped polysilicon layer, and the PMOS gate dielectric layer 93 may be formed to include a high-k dielectric layer such as a hafnium silicate (HfSiO) layer, so that threshold voltage Vth of the PMOS transistor may be modulated.

A second gate capping pattern 97 may be formed covering the PMOS gate electrode 96. The second gate capping pattern 97 may be formed of, e.g., an insulating layer such as a silicon nitride layer. Second spacers 99 may be formed on sidewalls of the PMOS gate electrode 96. The second spacers 99 may be formed of, e.g., a silicon oxide layer, a silicon oxynitride layer, a silicon nitride layer, or a combination thereof.

Next, source and drain regions may be formed by doping p-type or n-type impurities into the cap layer and the buffer pattern adjacent to the gate electrode. N-type source and drain regions may be formed in the tensile silicon cap layer 72 adjacent to opposite sides of the NMOS gate electrode 85, e.g., by introducing an N-type impurity such as phosphorus, etc. The NMOS gate electrode 85, the tensile silicon cap layer 72 crossing below the NMOS gate electrode 85, and the source and drain regions may constitute an NMOS transistor. The tensile silicon cap layer 72 crossing below the NMOS gate electrode 85 may be formed of the tensile strained silicon layer. As a result, an NMOS transistor having excellent mobility characteristics may be implemented.

P-type source and drain regions may be formed in the silicon cap layer 73 and the second buffer pattern 63 adjacent to both sides of the PMOS gate electrode 96, e.g., by introducing a P-type impurity such as boron, etc. The PMOS gate electrode 96, the second buffer pattern 63 crossing below the PMOS gate electrode 96, and the source and drain regions may constitute a PMOS transistor. The second buffer pattern 63 crossing under the PMOS gate electrode 96 may be formed of a silicon-germanium layer having a compressive stress. As a result, the PMOS transistor having excellent mobility characteristics may be implemented.

According to the first embodiment described above, the first buffer pattern 62 having a very thin thickness may be recrystallized to form the strained relaxation buffer pattern 62G having the graded germanium profile, in which the germanium concentration in the strained relaxation buffer pattern 62G decreases toward the first active region 52, and increases toward the tensile silicon cap layer 72. In addition, the buffer patterns 62 and 63 may be formed on the active regions 52 and 53 after the isolation layer 55 is formed. Accordingly, the strained relaxation buffer pattern 62G, the second buffer pattern 63, the tensile silicon cap layer 72, and the silicon cap layer 73 may be prevented from being deteriorated due to a thermal stress.

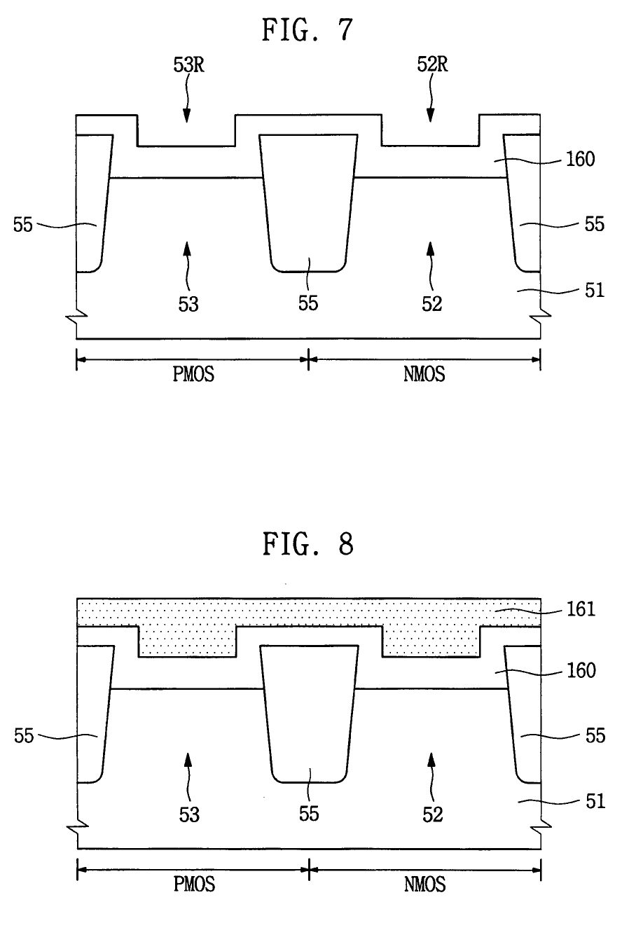

FIGS. 7 to 12 illustrate cross-sectional views of stages in a method of fabricating a semiconductor device having a thin strained relaxation buffer pattern according to a second embodiment. Referring to FIG. 7, as described with reference to FIGS. 1 and 2, a method of fabricating a semiconductor device according to the second embodiment may include forming an isolation layer 55 defining first and second active regions 52 and 53 in a semiconductor substrate 51. The semiconductor substrate 51 may be, e.g., a silicon (Si) substrate such as a silicon wafer. The semiconductor substrate 51 may include an NMOS region and a PMOS region. The isolation layer 55 may be formed of an insulating layer such as a silicon oxide layer. Exposed surfaces of the active regions 52 and 53 may be etched to form recessed regions 52R and 53R, which may have respective top surfaces that are lower than the top surface of the isolation layer 55.

A buffer layer 160 may be formed on the semiconductor substrate 51 having the active regions 52 and 53. The buffer layer 160 may be formed to cover the active regions 52 and 53 and the isolation layer 55. The buffer layer 160 may be formed of, e.g., a silicon-germanium layer or a germanium layer, and may be formed using a deposition technique. The buffer layer 160 may be formed to a thickness of about 1 nm to about 300 nm.

The buffer layer 160 may be formed along the surfaces of the recessed regions 52R and 53R, and across the isolation layer 55. The surface of the buffer layer 160 may be formed to have concave regions where it overlies the recessed regions 52R and 53R. In an implementation, a surface of the buffer layer 160 where it overlies the recessed regions 52R and 53R may be lower than the surface of the isolation layer 55.

Referring to FIG. 8, a sacrificial layer 161 may be formed on the buffer layer 160. The sacrificial layer 161 may be formed to cover the semiconductor substrate 51. The sacrificial layer 161 may be formed of a material layer having an etch selectivity with respect to the buffer layer 160. For example, the sacrificial layer 161 may be formed of a silicon oxide layer or a silicon nitride layer. In another implementation (not shown), the sacrificial layer 161 may be omitted.

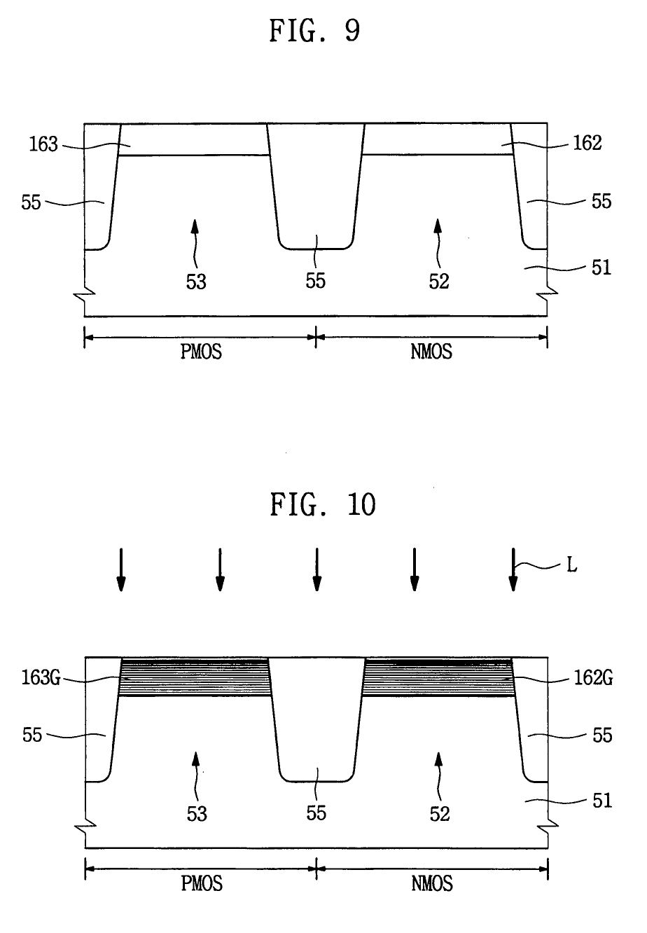

Referring to FIG. 9, the sacrificial layer 161 and the buffer layer 160 may be planarized so that a first buffer pattern 162 may be formed on the first active region 52, and a second buffer pattern 163 may be formed on the second active region 53. The sacrificial layer 161 may act to prevent surfaces of the buffer patterns 162 and 163 from being non-uniformly formed while the planarization is performed, such that the buffer patterns 162 and 163 may be formed to a uniform thickness. The buffer patterns 162 and 163 may be formed to a thickness of about 1 nm to 300 nm. In an implementation, the buffer patterns 162 and 163 may be formed to a thickness of about 10 nm to about 20 nm.

A chemical mechanical polishing (CMP) process, an etch-back process, or a combination thereof may be used for the planarization. For example, a CMP process using the isolation layer 55 as a stop layer may be employed for the planarization. In this case, the sacrificial layer 161 may partially remain on the buffer patterns 162 and 163. An isotropic etching process may be used to remove any remaining sacrificial layer 161. In another implementation, an etch-back process by which the sacrificial layer 161 and the buffer layer 160 are etched until the isolation layer 55 is exposed may be employed for the planarization.

Referring to FIG. 10, both of the buffer patterns 162 and 163 may be recrystallized to form strained relaxation buffer patterns 162G and 163G. The first strained relaxation buffer pattern 162G may be formed on the first active region 52 of the NMOS region, and the second strained relaxation buffer pattern 163G may be formed on the second active region 53 of the PMOS region.

A LEG process may be employed for the recrystallization of the buffer patterns 162 and 163. The LEG process may include irradiating a laser L onto the buffer patterns 162 and 163. The laser L irradiated onto the first and second buffer patterns 162 and 163 may have an energy density high enough to melt the first and second buffer patterns 162 and 163. In an implementation, an entire thickness of the first buffer pattern 162 and an entire thickness of the second buffer pattern 163 may be melted. In an implementation, the entire thickness of the first and second buffer patterns 162 and 163 may be melted, and respective top surfaces of the first and second active regions 52 and 53 that underlie the first and second buffer patterns 162 and 163 may also be melted. Melting of the germanium buffer patterns 162 and 163 may melt a portion of the underlying silicon layer in the active regions 52 and 53, such that silicon is incorporated into the germainum buffer patterns 162 and 163.

Through the LEG process, silicon and germanium in the buffer patterns 162 and 163 may be melted, and then recrystallized to form the strained relaxation buffer patterns 162G and 163G. The strained relaxation buffer patterns 162G and 163G may exhibit a graded germanium profile as a result of the melting and recrystallization, such that the germanium concentration profile in the strained relaxation buffer patterns 162G and 163G may decrease toward the active regions 52 and 53, and increase toward the top surfaces of the strained relaxation buffer patterns 162G and 163G. The top surfaces of the strained relaxation buffer patterns 162G and 163G may have a relaxed structure due to a difference in lattice constant between the germanium and the Si.

As described above, the LEG process may be applied to recrystallize the surfaces of the strained relaxation buffer patterns 162G and 163G, so that the relaxed structure may be formed. The strained relaxation buffer patterns 162G and 163G having the graded germanium profile may be formed using the very thin buffer patterns 162 and 163 having a thickness of about 10 nm to about 20 nm.

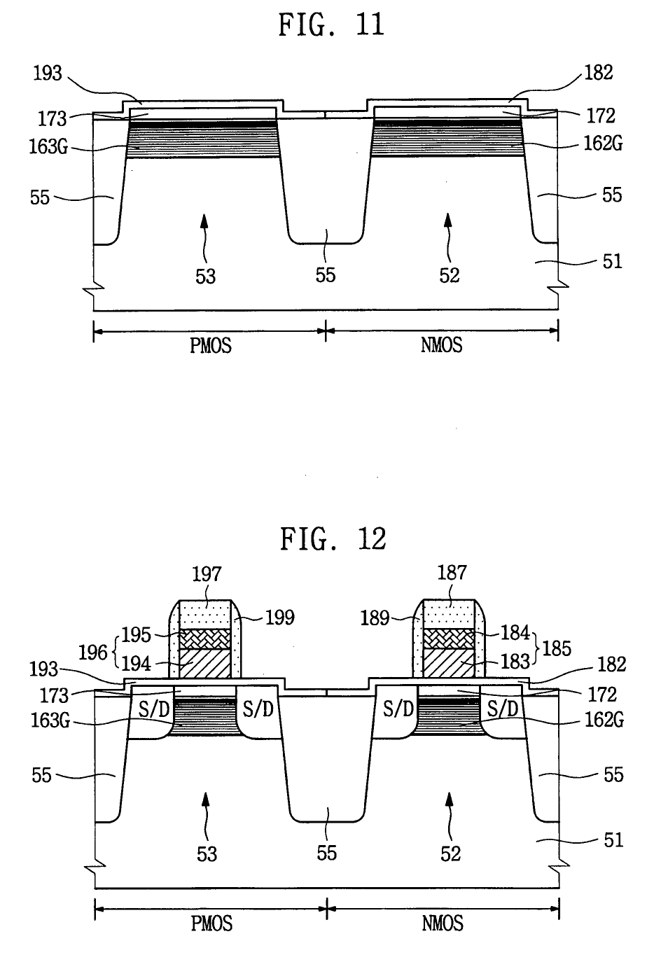

Referring to FIG. 11, first and second tensile silicon cap layers 172 and 173 may be formed on the first and second strained relaxation buffer patterns 162G and 163G, respectively. A SEG technique may be used to form the tensile silicon cap layers 172 and 173. The tensile silicon cap layers 172 and 173 may exhibit tensile strain in the silicon layer due to effects of the strained relaxation buffer patterns 162G and 163G. That is, the relaxed structure of the strained relaxation buffer patterns 162G and 163G may produce tensile strain in the silicon layers of the tensile silicon cap layers 172 and 173.

An NMOS gate dielectric layer 182 may be formed on the first tensile silicon cap layer 172. The NMOS gate dielectric layer 182 may be formed of, e.g., a silicon oxide layer, a silicon oxynitride layer, a silicon nitride layer, a high-k dielectric layer, or a combination thereof.

A PMOS gate dielectric layer 193 may be formed on the second tensile silicon cap layer 173. The PMOS gate dielectric layer 193 may be formed of, e.g., a silicon oxide layer, a silicon oxynitride layer, a silicon nitride layer, a high-k dielectric layer, or a combination thereof.

Referring to FIG. 12, an NMOS gate electrode 185 crossing the first tensile silicon cap layer 172 may be formed on the NMOS gate dielectric layer 182. A first polysilicon pattern 183 and a first silicide pattern 184 may be sequentially stacked to form the NMOS gate electrode 185. The first polysilicon pattern 183 may be formed of, e.g., an impurity-doped polysilicon layer. The first silicide pattern 184 may be formed of, e.g., a metal silicide layer such as a TiSi layer, a TaSi layer, a WSi layer, or a NiSi layer.

A first gate capping pattern 187 may be formed covering the NMOS gate electrode 185. The first gate capping pattern 187 may be formed of, e.g., an insulating layer such as a silicon nitride layer. First spacers 189 may be formed on sidewalls of the NMOS gate electrode 185. The first spacers 189 may be formed of, e.g., a silicon oxide layer, a silicon oxynitride layer, a silicon nitride layer, or a combination thereof.

A PMOS gate electrode 196 crossing the second tensile silicon cap layer 173 may be formed on the PMOS dielectric layer 193. A second polysilicon pattern 194 and a second silicide pattern 195 may be sequentially stacked to form the PMOS gate electrode 196. The second polysilicon pattern 194 may be formed of, e.g., an impurity-doped polysilicon layer. The second silicide pattern 195 may be formed of, e.g., a metal silicide layer such as a TiSi layer, a TaSi layer, a WSi layer, or a NiSi layer.

A second gate capping pattern 197 may be formed covering the PMOS gate electrode 196. The second gate capping pattern 197 may be formed of, e.g., an insulating layer such as a silicon nitride layer. Second spacers 199 may be formed on sidewalls of the PMOS gate electrode 196. The second spacers 199 may be formed of, e.g., a silicon oxide layer, a silicon oxynitride layer, a silicon nitride layer, or a combination thereof.

Source and drain regions (not shown) may be formed in the first tensile silicon cap layer 172 adjacent to opposite sides of the NMOS gate electrode 185. The NMOS gate electrode 185, the first tensile silicon cap layer 172 crossing under the NMOS gate electrode 185, and the source and drain regions may constitute an NMOS transistor. The first tensile silicon cap layer 172 crossing under the NMOS gate electrode 185 may be formed of the tensile strained silicon layer. As a result, an NMOS transistor having excellent mobility characteristics may be implemented.

Source and drain regions may be formed in the second tensile silicon cap layer 173 adjacent to opposite sides of the PMOS gate electrode 196. The PMOS gate electrode 196, the second tensile silicon cap layer 173 crossing under the PMOS gate electrode 196, and the source and drain regions may constitute a PMOS transistor.

When a low tensile stress is applied to a channel region, carrier mobility in the PMOS transistor may decrease. In contrast, when a high tensile stress is applied to the channel region, the carrier mobility in the PMOS transistor may increase. The second tensile silicon cap layer 173 crossing under the PMOS gate electrode 196 may be formed of the tensile strained silicon layer. Therefore, the PMOS transistor having excellent mobility characteristics may be implemented.

According to the second embodiment as described above, the buffer patterns 162 and 163 with a very thin thickness may be recrystallized using the LED process, so that the strained relaxation buffer patterns 162G and 163G having the graded germanium profile may be formed. A germanium concentration in the strained relaxation buffer patterns 162G and 163G may decrease toward the active regions 52 and 53, and may increase toward the tensile silicon cap layers 172 and 173. Also, the buffer patterns 162 and 163 may be formed on the active regions 52 and 53 after the isolation layer 55 is formed. As a result, the strained relaxation buffer patterns 162G and 163G and the tensile silicon cap layers 172 and 173 may be prevented from being deteriorated due to a thermal stress.

According to the embodiments described above, after an isolation layer defining active regions is formed in a semiconductor substrate, a buffer pattern formed of silicon-germanium or germanium may be formed on the active region. The LEG process may be employed to recrystallize the buffer pattern, thereby forming a strained relaxation buffer pattern. In this case, the very thin strained relaxation buffer pattern having a thickness of about 1 nm to about 300 nm may be sufficient to obtain a graded germanium profile. A germanium concentration in the strained relaxation buffer pattern may decrease toward the underlying substrate and may increase toward the top surface of the strained relaxation buffer pattern, such that the surface of the strained relaxation buffer pattern may exhibit a relaxed structure due to a difference in lattice constant between germanium and silicon. A SEG technique may be employed to form a tensile silicon cap layer on the strained relaxation buffer pattern. Consequently, a semiconductor device having a thin strained relaxation buffer pattern may be implemented.

Exemplary embodiments have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a semiconductor device, comprising:
forming a buffer pattern on a substrate, the buffer pattern including germanium;
recrystallizing the buffer pattern to form a strained relaxation buffer pattern; and
forming a tensile silicon cap on the strained relaxation buffer pattern, the cap being under tensile strain.

2. The method as claimed in claim 1, wherein a concentration of germanium in the strained relaxation buffer pattern increases in a direction from the substrate toward the cap.

3. The method as claimed in claim 1, wherein the buffer pattern is a silicon-germanium buffer pattern.

4. The method as claimed in claim 1, wherein the buffer pattern is a germanium buffer pattern.

5. The method as claimed in claim 1, wherein recrystallizing the buffer pattern includes a LEG process.

6. The method as claimed in claim 5, wherein the LEG process includes irradiating a laser onto the buffer pattern so as to melt the buffer pattern and a surface of the substrate underneath the buffer pattern.

7. The method as claimed in claim 1, further comprising, prior to recrystallizing the buffer pattern, forming an isolation layer defining an active region in the substrate, and recessing a top surface of the active region.

8. The method as claimed in claim 7, wherein the isolation layer is formed prior to forming the buffer pattern.

9. The method as claimed in claim 1, wherein the buffer pattern is formed to a thickness of about 1 nm to about 300 nm.

10. The method as claimed in claim 1, wherein the buffer pattern is formed to a thickness of about 10 nm to about 20 nm.

11. The method as claimed in claim 1, further comprising forming a gate electrode over the cap, such that the cap is interposed between the gate electrode and the strained relaxation buffer pattern, and the strained relaxation buffer pattern crosses beneath the gate electrode.

12. The method as claimed in claim 11, wherein the gate electrode is a gate electrode of an NMOS transistor, the method further comprising forming a PMOS transistor adjacent to the NMOS transistor.

13. The method as claimed in claim 12, wherein forming the PMOS transistor includes:
forming a second buffer pattern on the substrate, the second buffer pattern including germanium,
forming a second cap on the second buffer pattern, and
forming a second gate electrode on the second cap.

14. The method as claimed in claim 13, wherein the buffer pattern and the second buffer pattern are formed at the same time.

15. The method as claimed in claim 13, wherein the buffer pattern and the second buffer pattern have a same thickness, and
the cap and the second cap have a same thickness.

16. The method as claimed in claim 13, wherein the second buffer pattern is not recrystallized.

17. The method as claimed in claim 16, further comprising, prior to recrystallizing the buffer pattern, forming a mask pattern that exposes the buffer pattern and covers the second buffer pattern, and
recrystallizing the buffer pattern using a LEG process.

18. The method as claimed in claim 16, wherein forming the PMOS transistor further includes introducing a P-type impurity into the second buffer pattern on opposite sides of the second gate electrode.

19. The method as claimed in claim 13, wherein the second buffer pattern is recrystallized to form a second strained relaxation buffer pattern prior to forming the second cap.
